(19) United States
(12) Patent Application Publication
(10) Pub. No.: US 2002/0163414 A1
(43) Pub. Date: Nov. 7, 2002

(54) Coil-based electronic & electrical components (such as coils, transformers, filters and motors) based on nanotechnology

(76) Inventors: Yaron Mayer, Jerusalem (IL); Al J.C. Baur, Kibbutz Ramat Hashofet, IL (US)

Correspondence Address: YARON MAYER, 21 AHAD HA'Am ST., JERUSALEM, 92151, IL

(21) Appl. No.: 10/016,968

(22) Filed: Dec. 13, 2001

(30) Foreign Application Priority Data
Dec. 13, 2000 (IL) 140281

(51) Int. Cl. H01F 27/30

(52) U.S. Cl. 336/199

(57) ABSTRACT

Coils coupled to magnetically soft cores are a very important building block in today's electronics, used for manipulating electromagnetic fields. They are very important, for example, for transformers, inductors, filters, oscillators, and motors. Apart from permeability, the most important characteristics of such cores are high flux density and low core losses. The smaller the magnetic pieces within the typically ceramic substance of the core can become, the better the permeability, high flux density, and low core losses, which means also faster reaction times. The present invention is intended to improve the efficiency and abilities of coils by using, instead of typical Ferrite cores, a core based on a substance containing nano-structures, which can be for example Bucky Balls or Bucky tubes. Various possible variations and combinations of this are shown. Another possible variation is using for example long macro-size Bucky tubes or bundles of them also as wires for the coil itself, since this makes the improvement of the coil's performance even much better because of the much higher conductivity of these wires compared to copper. Therefore, the main problem for having also this additional feature is how to create longer nano-tubes for the wires. Various possible preferable solutions to this problem are discussed.

### BACKGROUND OF THE INVENTION

1. Field of the invention:

The present invention relates to magnetically responsive and electromagnetic components, and more specifically to coil-based electronic & electrical components (such as coils, transformers, filters and motors) based on nano-size components.

2. Background

Coils are a very important building block in today's electronics. They are very important, for example, for transformers, inductors, filters, oscillators, and motors. These components are typically used, among other things, in products such as: computers, computer peripherals, cable TV systems, radio, television receivers, EMI/RFI filters, specialized electronic instruments, switch-mode power supplies, aerospace navigational systems, specialized commercial and military communication systems, and many more. The general functionality of these core and coil combinations can be defined as manipulating electromagnetic fields for purposes such as voltage conversion, frequency filtering, creating mechanical motion, creating electromagnetic waves, etc. These coils work better the higher the magnetic responsiveness of the internal core around which they are rolled or, in other words, the magnetic permeability or “softness” of the core. Current sate-of-the-art coils typically use Ferro-magnetic cores in various shapes, around which one or more coils of electrically insulated electrically conducting wires are wound. The most common core used is magnetically-soft Ferrite, which is typically constructed from iron oxide and with one or more of other elements (such as Zinc, Magnesium, Manganese, and Nickel) mixed within a ceramic substance. These cores come in a variety of shapes, such as rods, tubes, sleeves, beads, bobbins, cup cores, cover plates for magnetic shields, transformer cores, and toroids (magnetic rings). Apart from permeability, the most important characteristics are high flux density and low core losses. The high magnetic permeability and these additional qualities are achieved because the resulting mixture reacts strongly to magnetic fields but is composed of small pieces of the magnetically responsive material, so that the magnetic field does not stay in the small pieces, and also less unwanted eddy currents can be created in them. Therefore, the smaller these pieces can become, the better the permeability, high flux density, and low core losses, which means also faster reaction times, so that for example faster electromagnetic pulses can be used, for example for broadcasting at shorter electromagnetic wavelengths. With the current methods, the ability to improve the state-of-the-art cores and coils is limited. In order to create better cores and coils, new approaches are needed.

### SUMMARY OF THE INVENTION

The present invention is intended to improve the efficiency and abilities of coils by using, instead of typical Ferrite cores, a core based on a substance containing nano-structures, which can be for example Bucky Balls or Bucky tubes. These are the most readily available nano-structures that can be created today, using carbon's tendency to self-construct in such structures under the appropriate conditions. Bucky Balls (the most common one of which has 60 carbon atoms) are shaped like a football with a combination of hexagons and pentagons on the surface, with a diameter of about 1 nanometer. Bucky Tubes are similarly shaped like hollow tubes, with a diameter of typically a few nanometers for single-wall tubes and more for multi-wall tubes, typically ending at both ends with closed curves like half-balls, and a length of usually a few dozens of nano-meters up to 300 microns (usually, this size is reached when a small group of Bucky-tubes grow together side by side, so the “wire” is even stronger than if it were made of a single tube). With current technology it is possible to convert about 70% of a given amount of graphite to Bucky balls, and with a slight change about 70% can be converted to Bucky tubes instead. These balls and tubes are available today already commercially for the price of around $30 per grams, which is just about 3 times more expensive than gold, and the price will continue to drop down considerably in the next few years. Researchers are currently trying to find out why the tube growth stops at about 300 microns. The Bucky tubes and Bucky balls have some unique features that make them extremely attractive: 1. They can conduct electricity about 10-100 times better than copper, 2. They are about a 100 times stronger than steel and weigh about 4-10 times less and are much more flexible, 3. They can chemically react with a large number of elements from the periodic table, so many compounds can be created with various impurities that can lead to more interesting qualities. These impurities are usually created during the forming of the Bucky structures by adding the required elements to the graphite vapors.

By using for example Bucky balls and/or Bucky tubes within the ceramic substance, much smaller elements can be created. Preferably, these balls or tubes contain also some impurities that make them respond in the magnetically required manner, such as for example a few atoms of Cobalt Or Nickel or Magnesium or Manganese or Iron or Zinc or additional elements or various combinations of these per ball, which makes them respond to magnetizations. The magnetic properties of these elements can be significantly altered by their incorporation with Bucky structures because of their nanometric size, their specific surface area and their tubular or round shapes. If Bucky tubes are used instead of balls, then preferably they are magnetized during the insertion into the ceramic substance in order to make them align in the same direction, preferably in the same direction of the elongation of the ceramic substance, however other alignment are also possibe. Since the Bucky balls are much smaller than the oxidized iron grains in typical state-of-the-art ferrites, coils with such core can be smaller, more efficient, and with faster response time. Also, because these balls are so small, they get much less unwanted internal currents, called Eddy currents, which makes them even more efficient. This can save energy and it can become quite cheap eventually, since graphite is a very abundant and cheaply available substance, so the productio of Bucky structures from it will probably keep going down considerably. However, there is a problem—the fact that the Bucky balls are such good conductors of electricity makes them again more subject to Eddy currents, whereas the best combination is elements that are magnetically responsive but less electrically conducting. Therefore, since Bucky balls stop conducting electricity for example if they are each filled up with six atoms of an Alkali metal, then preferably the Bucky balls are made each with six atoms like this or with other combinations that make them less conducting, but in a way that makes them still magnetizeable, for example if at least some of these atoms are Cobalt or Iron, or Zinc, or Magnesium, or Nickel, or Manganese (Mn), or various combinations of these. Another solution is using Bucky tubes which are semi-conductors or non-conductors, which depends for example on the zigzag structure of the hexagons, as explained in FIG. 2, and/or preferably adding also some appropriate impurities similar to those that can be added to the Bucky balls. Another advantage of the Bucky balls and Bucky tubes is that because of their envelope-like structure they have a large internal space. This can be very useful, since magnetic materials that have internal air gaps are known to work better as cores, because the distributed air gap allows the core to store higher levels of magnetic flux and prevents early saturation of the core. For example, for inductors, cores that have air gaps are desirable because they can maintain their constant permeability levels up to high dc or ac drive levels. Of course, the core can also be based on various mixtures of Bucky balls and Bucky tubes in various ratios, and can also contain for example a mixture of normal ferromagnetic particles mixed with Bucky structures at certain ratios, in order to make it cheaper. Another variation is adding the appropriate molecules or atoms inside the Bucky tubes or balls, in order to increase the magnetic density (apart from or in addition to adding them as impurities in their envelopes) for example by shooting them at the Bucky balls or tubes with high energy. So by encasing for example the appropriate magnetic atoms within a Bucky Ball or tube that is made to be a bad conductor for electricity we can use high density of the magnetic material with still good separation between them, and since Bucky balls for example are only about 1 nanometer in diameters, we get a much finer and structured grain than just using nanopowder of the magnetic materials. Another possible variation is to use for example some other material for encasing small groups of magnetic atoms, such as for example some organic material, protein, etc. Another variation is using nanoscale powders of the appropriate elements (such as Zinc, Magnesium, Nickel, Manganese, etc.) and/or various oxides of them (since the oxides are worse conductors of electricity) with or without the addition of Bucky structures, and mix them for example in the ceramic of the core. If such nano powder is used without Buckey elements, then preferably nano-size air or other gas bubbles are added for example by some fermentation process in order to improve the insulation between the magnetic grains. By using these improved cores, better transformers, inductors, filters, oscillators, motors, and other coil-based components, can be made.

Another possible variation is using for example long macro-size Bucky tubes or bundles of them also as wires for the coil itself, since this makes the improvement of the coil's performance even much better because of the much higher conductivity of these wires compared to copper. Therefore, the main problem for having also this additional feature is how to create longer nano-tubes for the wires. Apart from trying to grow them, which is what current researches in the area are mainly trying to do, or creating nano-Velcro, which means short twisted nanotubes that are supposed to connect to each other in a chain formation, as other researchers are tying, it might be possible to chemically glue together for example short Bucky Tubes or make them fuse directly, or make them condense within more constrained channels, which can increase the chance of growing larger tubes. A few possible ways of doing this are described in reference to FIG. 6. Of course, the Bucky-based core can be used also with normal coils instead of Bucky-based coils, and Bucky-based coils can be used also with normal cores.

### BRIEF DESCRIPTION OF THE DRAWINGS

FIG. 1 is an illustration of a typical structure of a Bucky ball.

FIG. 2 is an illustration of the typical structures of a few types of Bucky tubes.

FIG. 3 is a photograph of a few typical shapes of ferrite core.

FIG. 4 is an illustration of a preferable example of a core based on a mixture containing Bucky balls.

FIG. 5 is an illustration of a preferable example of a core based on a mixture containing Bucky tubes.

FIG. 6 is an illustration of an example of a mask helping to create larger macro-size wires based on Bucky tubes.

### IMPORTANT CLARIFICATION AND GLOSSARY

Throughout the patent when variations or various solutions are mentioned, it is also possible to use various combinations of these variations or of elements in them, and when combinations are used, it is also possible to use at least some elements in them separately or in other combinations. These variations are preferably in different embodiments. In other words: certain features of the invention, which are described in the context of separate embodiments, may also be provided in combination in a single embodiment. Conversely, various features of the invention, which are described in the context of a single embodiment, may also be provided separately or in any suitable sub-combination. All these drawings are just exemplary diagrams. They should not be interpreted as literal positioning, shapes, angles, or sizes of the various elements. Although the nano-structures are described with reference mainly to Bucky Balls and Bucky tubes, this invention is not limited to this kind of nano-structures, and can be used also with other types of nano-structures with appropriate qualities, in other shapes and/or other materials, as they become available. Although the cores have been described mainly in reference to a ceramic substrate containing the magnetically responsive parts, this is just an example and other materials can also be used, such as various polymers.

### DETAILED DESCRIPTION OF THE PREFERRED EMBODIMENTS

All of the descriptions in this and other sections are intended to be illustrative examples and not limiting

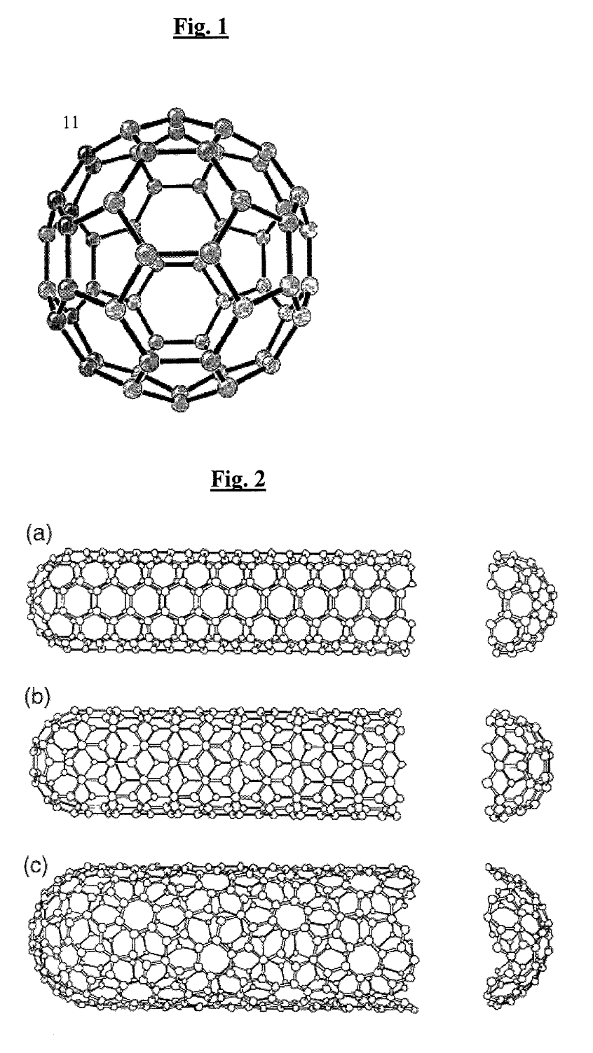

Referring to FIG. 1, we show an illustration of the structure of a C60 Bucky ball (11), made of carbon atoms with surfaces of hexagons and pentagons. The Bucky ball has a diameter of about 1 nano-meter and can trap small atoms or molecules within the inner space of the ball, however a strong force is needed to overcome atomic resistance forces for passing through between the atoms of the ball's envelope. When adding impurities to the ball, such as Alkali metals for even better conductivity, or Cobalt for magnetizability, they typically combine with a few specific sites on the surface of the ball.

Referring to FIG. 2, we show an illustration of the typical structures of a few types of Bucky tubes, with a cross-section of their pattern at the side. Single-wall Bucky tubes (such as tube ‘a’) are typically with a diameter of about 4 nanometers and multi-wall tubes can be for example 20 nanometers in diameters. The length can be any length but in practice most are between a few dozens of nanometers to about 300 micron, and attempts are being made to find out why their growth typically doesn't go beyond that with the creation methods that are used today. Their electrical conductivity depends on the tube's diameter and on the chiral angle between the nanotube's axis and the zigzag direction. Tubes with straight lines of hexagons (like ‘a’) are great conductors, whereas tubes with a zigzag pattern are typically semiconductors.

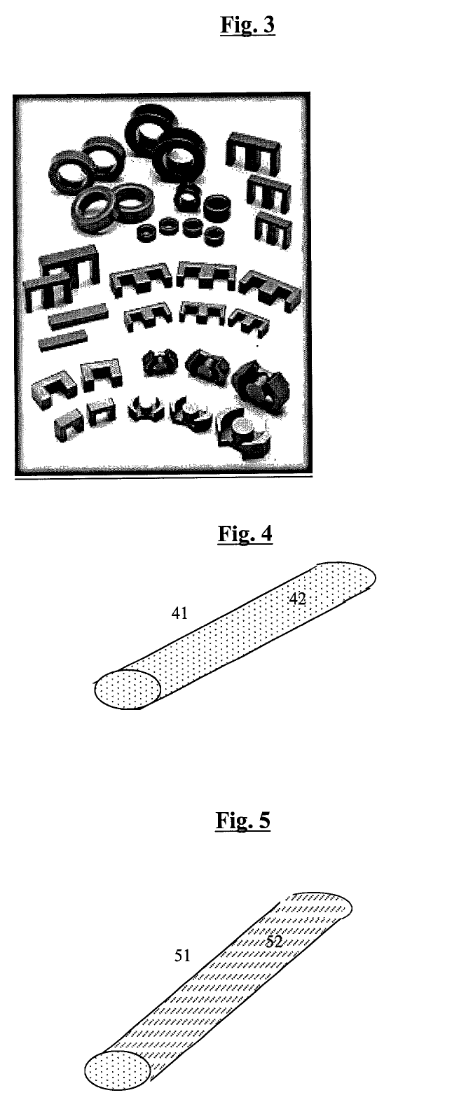

Referring to FIG. 3, we show a photograph of a few typical shapes of ferrite core. As can be seen, some cores are shaped like a rod, some are shaped like a ring (toroid), some are shaped like the letter E, some are shaped like half an E, some are shaped like an E with a fatter round element in the median fork, etc. The required shape and size depend on the application, space constraints, temperature limitations, assembly considerations, etc. For example the various E-shaped cores are typically used in transformers.

Referring to FIG. 4, we show an illustration of a core (41) based on a mixture containing Bucky balls (42). Of course the relative sizes that can be depicted are not exact, since the Bucky balls are much smaller than the rod and much more balls are in each core. Typically, the granularity of the metallic parts in normal ferrite is a little bellow 1 micron, so using Bucky balls creates a much finer granularity. Also, different concentrations of the Bucky balls (and/or tubes) and/or of the magnetic elements inside them can be used for various required frequencies, so that, for example, for higher frequencies cores with a smaller concentration of Bucky balls are preferable, and for lower frequencies cores with a higher concentration of Bucky balls are preferable. Similarly, different impurities can be used for different requirements, so that for example MnZn (Manganese—Zinc) impurities can be better for lower frequencies and NiZn (Nickel—Zinc) impurities can be better for higher frequencies. Preferably, the Bucky balls are each filled up in their envelope with the appropriate number of atoms that makes them non-conducting or less conducting electrically, and preferably field with the magnetic impurities within their inner space, but some or these elements might be included also in addition or instead in their envelope. Of course, this is just an example of a rod-shaped core, and similarly other shapes and sizes of cores can be built containing Bucky balls. Another possible variation is to create for example alternating arrays of non-magnetic Bucky balls (and/or Bucky tubes) and arrays of magnetic Buckey balls (and/or Bucky tubes), which allows high levels of close proximity with still separation of the magnetic elements. This can be accomplished for example by using strong magnetic field lines during the production process. Preferably this is done with a ceramic substance that can be made viscose or semi-solid for example chemically at low temperatures, so that this order can be kept before heating to levels that make the magnetic fields ineffective. Another possible variation is to use a similar process with magnetic field lines during the production process for example with nanoscale powders of the appropriate elements (such as Zinc, Magnesium, Nickel, Manganese, etc.), so that they can be spaced together very closely with thin layers of non-magnetic or electrically isolating layers between them. Another possible variation is to use such structures for example for highly sensitive electromagnetic sensors, for example for hard-disk heads. Another possible variation is using for example Bucky balls that have been treated by the new discovery of Makarova el. al., published on Nature magazine on Oct. 18, 2001, that heating and compressing the balls can force them to join together in layers like sheets or bubble wrap which then display magnetic behavior at room temperature even without adding magnetic impurities. (Possibly this can be done also for example with Bucky tubes). However, this means larger chunks of material, and another problem is that the resulting material has higher hysteresis, so it might be necessary for example to break them up again to smaller parts and play with more or less homogenity in order to reduce the hysteresis. Another possible variation is to use Makarova's method in combination with various magnetic impurities. Of course various combinations of the above and other options are also possible. Preferably the manufacturing is done in conditions of absence of Oxygen, such as for example in an environment of various other gases, since absorbing oxygen can make Buckey balls or Bucky tubes better conductors of electricty.

Referring to FIG. 5, we show an illustration of a core (51) based on a mixture containing Bucky tubes (52). Everything that was described in relation to FIG. 4 is also relevant here, except that in addition, the electrical conductivity of the Bucky tubes can be controlled also by using tubes that are inherently less conducting because of their envelope patterns. Also, preferably the Bucky tubes are all aligned in the same direction as the rod. Another possible variation is that the Bucky tubes are aligned for example at 90 degrees to the direction of the rod, which has the advantage of even further reduced electrical conductivity because Bucky tubes conduct much less electricity in their width than in their length. Another possible variation is to use other angles and/or for example to use Bucky tubes which go in various different angles instead of tubes that all go in the same direction, and/or mix them with buckey balls and/or other elements, which might help for example to reduce inductions and/or other possible interactions between them. Of course, this is just an example of a rod-shaped core, and similarly other shapes and sizes of cores can be built containing Bucky tubes. The format of division into rows of nano-tubes is just an artifact caused by the drawing tools, and many formats are of course possible in reality. Preferably the manufacturing is done in conditions of absence of Oxygen, such as for example in an environment of various other gases, since absorbing oxygen can make Buckey balls or Bucky tubes better conductors of electricity.

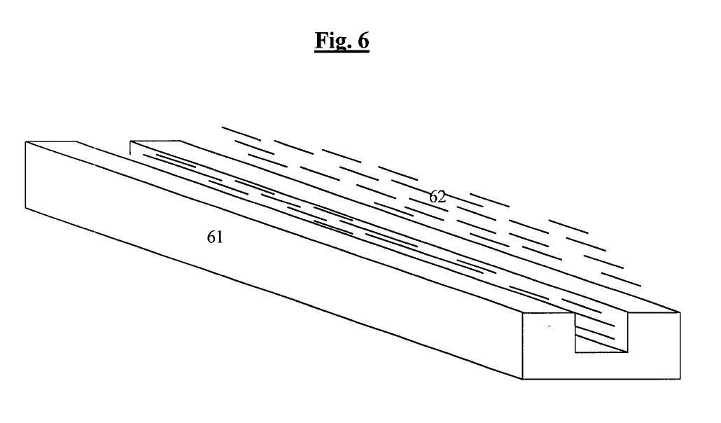

Referring to FIG. 6, we show an illustration of an example of a mask (61) helping to create larger macro-size wires based on Bucky tubes (62) that are condensed in the mask. For clarity of the illustration the mask is quite wide compared to the Bucky tubes shown, but in reality it can be much closer to their width. For example a mask based on extreme UV lithography can create a channel 20 nanaometeres wide, which is just 5 times wider than a 4-nano diameter Bucky-tube. One preferably way of creating longer nano-tubes is to grow nano-tubes that contain also for example Cobalt and/or other magnetic impurities, which makes them magnetizeable, and then use an electromagnetic field in order to control their orientation and positioning (or use for example an electrostatic field for this, or both and/or for example ultrasonic acoustic waves), and then for example use holograms or extreme UV lithography in order to create masks or wave-guides for them to align in the required shape, and then bind them together, preferably by chemical means, for example with gold atoms, which are good and stable electrical conductors. Another possible variation is combining the recently developed extreme-UV lithography with the graphite vapors used in the process of creating the nano-tubes, so that the heated graphite vapors are condensed around the mask created with this lithography, so that the tubes grow specifically in the areas outlined by the mask. In addition to this, adding pressure and/or heat and/or various gases to the vapors might help this even further. Another variation is to align the Bucky tubes in the same direction (for example by electromagnetic fields or electrostatic charge) and condense them in a small elongated space (such as with the extreme UV mask or by other means), and then for example bombard them with a beam of strong energy additional Bucky tubes or Bucky balls or other Carbon particles or carbon atoms or other atoms, which can make them fuse together, facing the desired direction, and/or apply for example a large atmospheric or mechanical pressure on them with or without additional heating, and/or use for example mathane gas with heat or microwave radiation on them, which can create thin diamond coatings and might help the bucky tubes fuse this way. Another possible variation is for example condensing the Graphite vapors between two or more electrodes in a strong electrical field which concentrates them in the same area, which can increase the chance of getting longer and thicker Bucky tubes. For creating even longer nano-wires, when a long mask is used, preferably it is either a very long mask, or the forming nano-wire is preferably pulled to one side in the appropriate speed for example by mechanical forces and/or magnetic and/or electric forces (for example spinning it on a wheel), so that the newly added nanotubes are preferably added near the end of the wire. Of course various combinations of the above and other variations can also be used.

While the invention has been described with respect to a limited number of embodiments, it will be appreciated that many variations, modifications, expansions and other applications of the invention may be made which are included within the scope of the present invention, as would be obvious to those skilled in the art.

We claim:

1. An electrical coil-based device based on at least some nano-scale structures, comprising:
At least one magnetically-soft core;
At least one coil made of an electrically insulated electrically conducting wire, wrapped around at least part of said core.

2. The device of claim 1 wherein said core contains nano-size structures within the substrate of the core.

3. The device of claim 2 wherein said nano-size structures are Bucky balls with impurities that make them magnetically responsive.

4. The device of claim 3 wherein said Bucky balls have impurities that make them less conducting electrically.

5. The device of claim 2 wherein said nano-size structures are Bucky tubes with impurities that make them magnetically responsive.

6. The device of claim 5 wherein said Bucky tubes are of types that are bad electrical conductors.

7. The device of claim 5 wherein said Bucky tubes have impurities that make them less conducting electrically.

8. The device of claim 6 wherein said Bucky tubes have impurities that make them less conducting electrically.

9. The device of claim 2 wherein said nano-size structures are a combination of Bucky balls and Bucky tubes.

10. The device of claim 1 wherein said electrical wires are based on Bucky tubes.

11. The device of claim 2 wherein said electrical wires are based on Bucky tubes.

12. A method of making electrical coil-based devices based on at least some nano-scale structures, comprising:
Providing at least one magnetically-soft core;
Providing at least one coil made of an electrically insulated electrically conducting wire, wrapped around at least part of said core.

13. The method of claim 12 wherein said core contains nano-size structures within the substrate of the core.

14. The method of claim 13 wherein said nano-size structures are Bucky balls with impurities that make them magnetically responsive.

15. The method of claim 14 wherein said Bucky balls have impurities that make them less conducting electrically.

16. The method of claim 13 wherein said nano-size structures are Bucky tubes with impurities that make them magnetically responsive.

17. The method of claim 16 wherein said Bucky tubes are of types that are bad electrical conductors.

18. The method of claim 16 wherein said Bucky tubes have impurities that make them less conducting electrically.

19. The method of claim 17 wherein said Bucky tubes have impurities that make them less conducting electrically.

20. The method of claim 13 wherein said nano-size structures are a combination of Bucky balls and Bucky tubes.

21. The method of claim 1 wherein said electrical wires are based on Bucky tubes.

22. The method of claim 1 wherein said electrical wires are based on Bucky tubes.

23. The method of claim 21 wherein said electrical wires are constructed from smaller bucky tubes by using an electromagnetic field in order to control their orientation and positioning.

24. The method of claim 21 wherein said electrical wires are constructed from smaller bucky tubes by using an electrostatic field in order to control their orientation and positioning.

25. The method of claim 21 wherein said electrical wires are constructed from smaller bucky tubes by using a holographic wave guide in order to control their orientation and positioning.

26. The method of claim 21 wherein said electrical wires are constructed from smaller bucky tubes by using a lithographically produced mask in order to control their orientation and positioning.

27. The Method of claim 25 wherein at least one of an electrostatic field and an electromagnetic field is used in order to control their orientation and positioning of the bucky tubes.

28. The Method of claim 26 wherein at least one of an electrostatic field and an electromagnetic field is used in order to control their orientation and positioning of the bucky tubes.

29. The method of claim 23 wherein said Bucky tubes are glued together by chemical means.

30. The method of claim 24 wherein said Bucky tubes are glued together by chemical means.

31. The method of claim 25 wherein said Bucky tubes are glued together by chemical means.

32. The method of claim 26 wherein said Bucky tubes are glued together by chemical means.

33. The method of claim 27 wherein said Bucky tubes are glued together by chemical means.

34. The method of claim 28 wherein said Bucky tubes are glued together by chemical means.

35. The method of claim 25 wherein said Bucky tubes are fused together by bombarding them with additional high energy carbon elements.

36. The method of claim 26 wherein said Bucky tubes are fused together by bombarding them with additional high energy carbon elements.

37. The method of claim 27 wherein said Bucky tubes are fused together by bombarding them with additional high energy carbon elements.

38. The method of claim 28 wherein said Bucky tubes are fused together by bombarding them with additional high energy carbon elements.

39. The method of claim 21 wherein said electrical wires are constructed by condensing graphite vapors into bucky tubes while using an electromagnetic field in order to control their orientation and positioning.

40. The method of claim 21 wherein said electrical wires are constructed by condensing graphite vapors into bucky tubes while using an electrostatic field in order to control their orientation and positioning.

41. The method of claim 21 wherein said electrical wires are constructed by condensing graphite vapors into bucky tubes while using a holographic wave guide in order to control their orientation and positioning.

42. The method of claim 21 wherein said electrical wires are constructed by condensing graphite vapors into bucky tubes while using a lithographically produced mask in order to control their orientation and positioning.

43. The method of claim 28 wherein high pressure is used in order to force the Bucky tubes to fuse together.

44. The method of claim 28 wherein methane gas and microwave radiation is used in order to attach additional carbon atoms to adjacent Bucky tubes.

45. A method of producing magnetic cores wherein magnetic field lines are used to better order the magnetically responsive elements within the core.
